(19) United States
(12) Patent Application Publication
(10) Pub. No.: US 2025/0253843 A1
(43) Pub. Date: Aug. 7, 2025

(54) GATE DRIVE CIRCUITRY

(71) Applicant: Mitsubishi Electric Corporation, Tokyo (JP)

(72) Inventors: Yuji NEMOTO, Tokyo (JP); Kohei ONDA, Tokyo (JP)

(73) Assignee: Mitsubishi Electric Corporation, Tokyo (JP)

(21) Appl. No.: 18/856,083

(22) PCT Filed: Apr. 26, 2022
(86) PCT No.: PCT/JP2022/018891

§ 371 Date: Oct. 11, 2024

(51) Int. Cl. H03K 17/16

(52) U.S. Cl. CPC H03K 17/166

(57) ABSTRACT

A gate drive circuitry for driving a main switching element connected in series with a main switching element includes: a controller that makes output to a gate terminal of the main switching element in a high-impedance state for a prescribed period when a drain-source voltage of the main switching element fluctuates during a turn-on action period, the turn-on action period being a period from a state change of the main switching element to completion of turning on of the main switching element, the state change being a change from a state in which the main switching element is kept turned off to a state in which the main switching element is in a turn-on state, the controller returning the output to the gate terminal of the main switching element to a turn-on action state; and a detector that detects a timing serving as a trigger to start the prescribed period.

### FIELD

The present disclosure relates to a gate drive circuitry.

### BACKGROUND

Conventionally, semiconductor elements such as insulated gate bipolar transistors (IGBTs) and metal oxide semiconductor field effect transistors (MOSFETs) are used as switching elements for use in power conversion apparatuses and the like. These switching elements each perform a switching action by receiving an output voltage of a drive circuitry. In addition, these switching elements cause switching loss when being turned on and off.

It is known that in a case where one of a pair of switching elements is turned on while current flows through a diode of the other switching element in an inverter, a converter, or the like including switching elements with a totem-pole configuration, a reverse recovery action occurs in the diode of the other switching element to cause a high surge voltage. A high surge voltage may exceed a withstanding voltage of the switching element to destroy the switching element. In addition, a high surge voltage may serve as noise to cause a malfunction of another device. It is possible to suppress occurrence of such a surge voltage by reducing the switching speed of the switching element.

It is possible to change the switching speed of a switching element by, for example, adjusting a resistance value of a gate resistor connected to a gate terminal of the switching element, or adjusting a gate voltage to be applied to the gate terminal. For the switching element, it is desirable to minimize an increase in switching loss while choosing a resistance value of the gate resistor such that a surge voltage falls within a specific range in which no problem is caused. For example, Patent Literature 1 discloses a technique for reducing switching noise by switching gate resistors in a transition period of the switching of a switching element.

### CITATION LIST

### Patent Literature

Patent Literature 1: Japanese Patent Application Laid-open No. 10-32976

### SUMMARY OF INVENTION

### Problem to be Solved by the Invention

However, the above-described conventional technique has a problem in that an additional switch and gate resistor are required so as to switch gate resistors and thus, a circuitry increases in size.

The present disclosure has been made in view of the above, and an object of the present disclosure is to obtain a gate drive circuitry capable of suppressing occurrence of a surge voltage and suppressing an increase in switching loss while suppressing an increase in circuit size.

### Means to Solve the Problem

To solve the above described problems and achieve the object, the present disclosure relates to a gate drive circuitry in which a first main switching element and a second main switching element are connected in series, and the gate drive circuitry makes the first main switching element a target to be driven. The gate drive circuitry includes a controller configured to make output to a gate terminal of the first main switching element in a high-impedance state for a prescribed period when a drain-source voltage of the first main switching element fluctuates during a turn-on action period that is a period from a state change of the first main switching element to completion of turning on of the first main switching element. The state change is a change from a state in which the first main switching element is kept turned off to a state in which the first main switching element is in a turn-on state, the drain-source voltage of the first main switching element is completely lowered when the turning on of the first main switching element is completed. And the controller returns the output to the gate terminal of the first main switching element to a turn-on action state after the prescribed period ends. The turn-on action state is a state observed before a start of the prescribed period, and the controller continues the turn-on action until the turning on of the first main switching element is completed. The gate drive circuitry further includes a detector configured to detect a timing serving as a trigger to start the prescribed period.

### Effects of the Invention

The gate drive circuitry of the present disclosure has an effect of suppressing occurrence of a surge voltage and suppressing an increase in switching loss while suppressing an increase in circuit size.

### BRIEF DESCRIPTION OF DRAWINGS

FIG. 1 is a diagram illustrating an exemplary configuration of a gate drive circuitry according to a first embodiment.

FIG. 2 is a diagram illustrating an exemplary configuration of a power conversion system including the gate drive circuitry according to the first embodiment.

FIG. 3 is a timing chart illustrating states of operation of the gate drive circuitry according to the first embodiment.

FIG. 4 is a flowchart illustrating operation of the gate drive circuitry according to the first embodiment.

FIG. 5 is a diagram showing an example of a configuration of processing circuitry that implements the gate drive circuitry according to the first embodiment in a case where the processing circuitry includes a processor and a memory.

FIG. 6 is a diagram showing an example of a configuration of processing circuitry that implements the gate drive circuitry according to the first embodiment in a case where the processing circuitry includes dedicated hardware.

FIG. 7 is a diagram illustrating an exemplary configuration of a gate drive circuitry according to a second embodiment.

FIG. 8 is a diagram illustrating an exemplary configuration of a gate drive circuitry according to a third embodiment.

### DESCRIPTION OF EMBODIMENTS

Hereinafter, gate drive circuitries according to embodiments of the present disclosure will be described in detail with reference to the drawings.

### First Embodiment

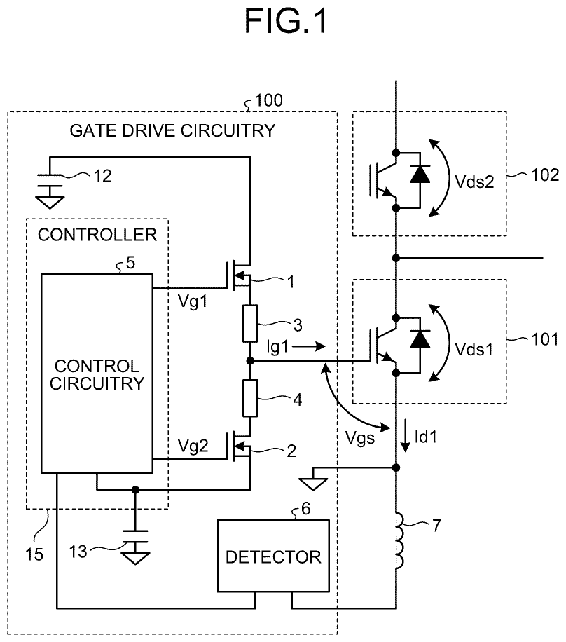

FIG. 1 is a diagram illustrating an exemplary configuration of a gate drive circuitry 100 according to a first embodiment. In a system in which the main switching element 101 and a main switching element 102 are connected in a totem-pole configuration, that is, connected in series, as illustrated in FIG. 1; the gate drive circuitry 100 makes a main switching element 101 as a target to be driven. In the following description, the main switching element 101 may be referred to as a first main switching 10 element, and the main switching element 102 may be referred to as a second main switching element. Although not illustrated in FIG. 1, another gate drive circuitry 100 (not illustrated) makes the main switching element 102 as a target to be driven.

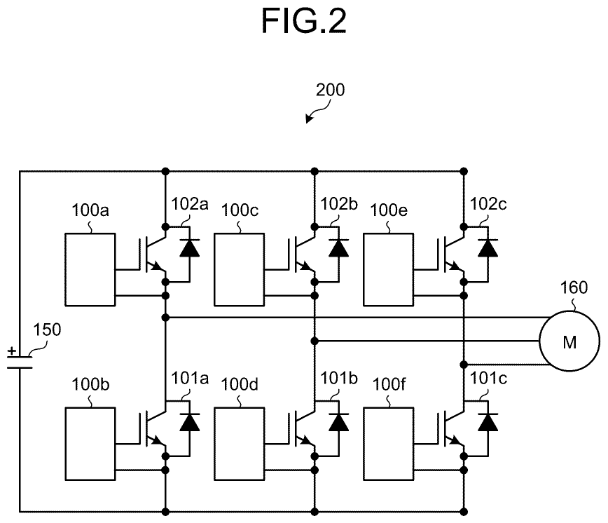

FIG. 2 is a diagram illustrating an exemplary configuration of a power conversion system 200 including the gate drive circuitry 100 according to the first embodiment. In FIG. 2, gate drive circuitries 100a to 100f have the same configuration as the gate drive circuitry 100 illustrated in FIG. 1. In addition, main switching elements 101a to 101c have the same configuration as the main switching element 101 illustrated in FIG. 1, and main switching elements 102a to 102c have the same configuration as the main switching element 102 illustrated in FIG. 1. The power conversion system 200 is a three-phase inverter system that converts direct-current power supplied from a direct-current power supply 150 into alternating-current power to be output to a load such as a motor 160. Note that the direct-current power supply 150 may be constituted by: a system power supply that outputs alternating-current power; a rectifier circuitry that rectifies the alternating-current power; and the like.

The main switching elements 101 and 102 to be driven by the gate drive circuitry 100 are power semiconductor elements such as IGBTs, but may be other voltage-driven switching elements such as MOSFETs. When each of the main switching elements 101 and 102 is constituted by an IGBT, a diode is connected in antiparallel to a semiconductor that performs switching. When each of the main switching elements 101 and 102 is constituted by a MOSFET, the diode to be connected in antiparallel to the semiconductor that performs switching can be substituted by a body diode of the MOSFET.

Next, a configuration of the gate drive circuitry 100 that makes the main switching element 101 as the target to be driven will be described in detail with reference to FIG. 1. As an example, a general constant-voltage drive circuitry is applied as the gate drive circuitry 100 in the present embodiment. As illustrated in FIG. 1, the gate drive circuitry 100 includes: switching elements 1 and 2; gate resistors 3 and 4; a detector 6; direct-current power supplies 12 and 13; and a controller 15. The controller 15 includes a control circuitry 5.

The switching element 1 is a first switching element having one end connected to the direct-current power supply 12 that is a first direct-current power supply. The switching element 1 is capable of outputting a voltage from another end to a gate terminal of the main switching element 101 via the gate resistor 3.

The switching element 2 is a second switching element having one end connected to the direct-current power supply 13 that is a second direct-current power supply. The switching element 2 is capable of outputting a voltage from another end to the gate terminal of the main switching element 101 via the gate resistor 4.

The gate resistor 3 is a gate resistor for adjusting the switching speed of the main switching element 101.

The gate resistor 4 is a gate resistor for adjusting the switching speed of the main switching element 101.

The direct-current power supply 12 is the first direct-current power supply for applying a positive voltage to the gate terminal of the main switching element 101. The direct-current power supply 12 is connected to the gate terminal of the main switching element 101 via the switching element 1 and the gate resistor 3.

The direct-current power supply 13 is the second direct-current power supply for applying a negative voltage to the gate terminal of the main switching element 101. The direct-current power supply 13 is connected to the gate terminal of the main switching element 101 via the switching element 2 and the gate resistor 4.

In the present embodiment, the switching elements 1 and 2 are MOSFETs, for example. Here, when a first voltage V1 is defined as the positive voltage to be applied from the direct-current power supply 12 to the gate terminal of the main switching element 101, and a second voltage V2 is defined as the negative voltage to be applied from the direct-current power supply 13 to the gate terminal of the main switching element 101, the following relationship is established as shown in formula (1) below.

V1>Mirror voltage of main switching element 101>V2 (1).

When the main switching element 101 is being turned on, a gate voltage Vgs of the main switching element 101 temporarily becomes flat at a specific voltage which is referred to as the mirror voltage of the main switching element 101.

In the controller 15, the control circuitry 5 controls operation of the switching elements 1 and 2 so as to control the voltages to be applied from the gate drive circuitry 100 to the gate terminal of the main switching element 101.

The controller 15 makes output to the gate terminal of the main switching element 101 in a high-impedance state for a single shot, that is, for a prescribed period when a drain-source voltage Vds1 of the main switching element 101 fluctuates during a turn-on action period. The turn-on action period is a period from a state change of the main switching element 101 to completion of the turning on of the main switching element 101. The state change is a change from a state in which the main switching element 101 is kept turned off to a state in which the main switching element 101 is in a turn-on state. The drain-source voltage Vds1 of the main switching element 101 is completely lowered when the turning on of the main switching element 101 is completed. After the end of the prescribed period, the controller 15 returns the output to the gate terminal of the main switching element 101 from the high-impedance state to a turn-on action state observed before the start of the prescribed period, and continues the turn-on action until the turning on of the main switching element 101 is completed.

In the present embodiment, by individually controlling the on/off of the switching element 1 and the switching element 2, the control circuitry 5 of the controller 15: controls the voltages to be output to the gate terminal of the main switching element 101; or brings the output to the gate terminal of the main switching element 101 into the high-impedance state. Operation of the control circuitry 5 of the controller 15 will be described below in detail.

The detector 6 detects a timing serving as a trigger to start the prescribed period during which the controller 15 makes the output to the gate terminal of the main switching element 101 in the high-impedance state. In the present embodiment, the detector 6 includes a circuitry that generates a signal corresponding to a single pulse when current flowing through the main switching element 101 enters a prescribed state, by determining the state of the current flowing through the main switching element 101 based on a voltage generated in a reactor 7. The signal is an example of a reference signal for generating a timing for switching gate driving states of the main switching element 101. Note that a timing to be detected by the detector 6 does not need to coincide with a timing of the start of the prescribed period for which the controller 15 makes the output to the gate terminal of the main switching element 101 in the high-impedance state. Actually, there is a delay time between these two timings. The delay time includes for example: a processing time from when the detector 6 detects a timing serving as a trigger to start the prescribed period to when the detector 6 outputs a signal; and a processing time from when the controller 15 acquires the signal from the detector 6 to when the controller 15 actually brings the output to the gate terminal of the main switching element 101 into the high-impedance state.

Outside the gate drive circuitry 100, the reactor 7 may be mounted, as an external component, on a substrate or the like on which the main switching element 101 is mounted. Alternatively, a parasitic inductance component located at a wiring portion of the substrate on which the main switching element 101 is mounted may be utilized as the reactor 7.

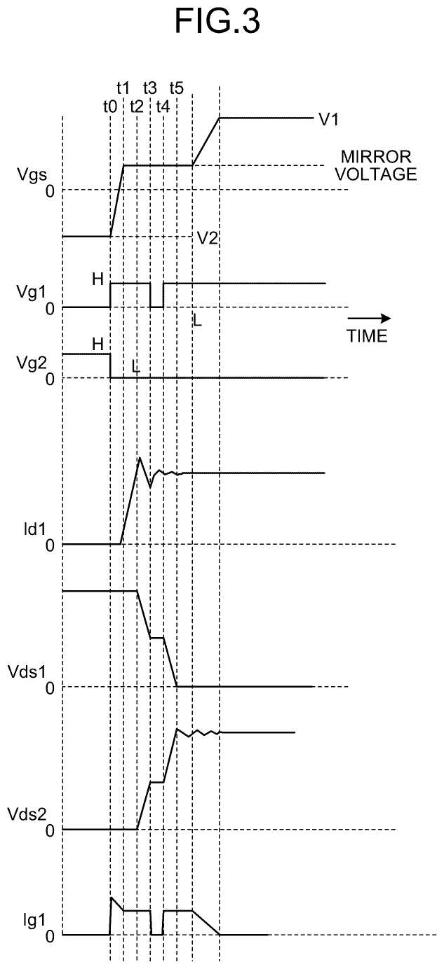

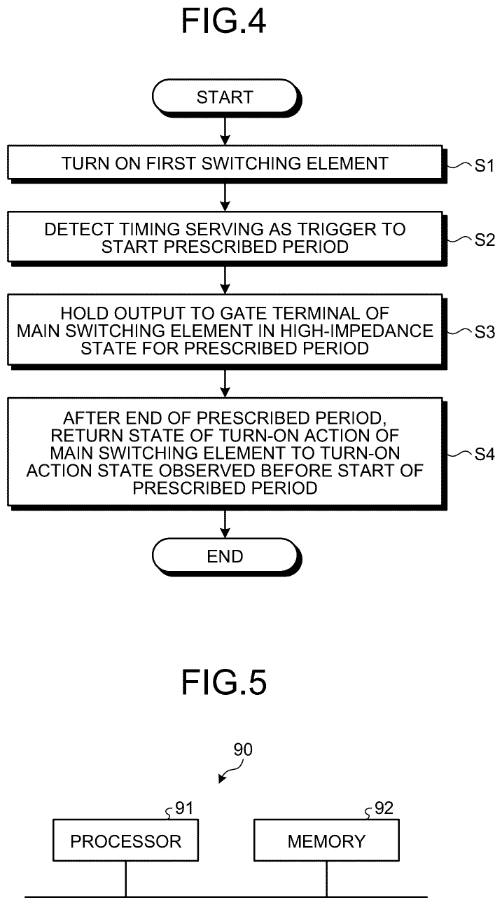

Next, operation of the gate drive circuitry 100 will be described with reference to a timing chart of FIG. 3. FIG. 3 is a timing chart illustrating states of operation of the gate drive circuitry 100 according to the first embodiment. FIG. 3 illustrates, in order from the top: the gate voltage Vgs being a voltage between the gate and source of the main switching element 101; a drive signal Vg1 with which the controller 15 turns on and off the switching element 1; a drive signal Vg2 with which the controller 15 turns on and off the switching element 2; a drain current Id1 of the main switching element 101; the drain-source voltage Vds1 of the main switching element 101; a drain-source voltage Vds2 of the main switching element 102; and a gate current Ig1 of the main switching element 101. Note that, in FIG. 3, the horizontal axis represents time. FIG. 4 is a flowchart illustrating operation of the gate drive circuitry 100 according to the first embodiment.

The control circuitry 5 sets the drive signal Vg1 for the switching element 1 to high (H) at time t0 to turn on the switching element 1 (step S1). As a result, the first voltage V1 is applied as the gate voltage Vgs to the gate terminal of the main switching element 101 via the gate resistor 3. Thus, the main switching element 101 is turned on at a normal switching speed. Here, the normal switching speed refers to a switching speed at which the main switching element 101 is turned on when the main switching element 101 is turned on with the first voltage V1 which is to be applied in an ON state.

When the gate voltage Vgs of the main switching element 101 reaches the mirror voltage at time t1, the main switching element 101 changes in conduction characteristic in a state where the gate voltage Vgs does not rise while injection of charges into the gate terminal is continued.

At this time, the drain current Id1 of the main switching element 101 gradually increases. Then, at time t2, the drain current Id1 reaches a drain current Id2 that was flowing through the main switching element 102 of a counterpart arm. Thereafter, the drain current Id1 of the main switching element 101 temporarily overshoots, and commutation of the current is completed while being accompanied by vibration damping. Here, the detector 6 detects, from the driving state of the main switching element 101, the timing serving as a trigger to start the prescribed period for which the output to the gate terminal of the main switching element 101 is held in the high-impedance state (step S2). In the present embodiment, the detector 6 detects a change that occurs when the drain current Id1 overshoots and vibration damping occurs, and outputs, to the control circuitry 5 of the controller 15, a signal indicating that the timing serving as a trigger to start the prescribed period has been detected just for a single shot. In practice, it is assumed that a delay time is included in a period from when the detector 6 detects the change in vibration damping of the drain current Id1 to when the detector 6 outputs the signal. Furthermore, at time t2, the drain-source voltage Vds1 of the main switching element 101 starts to decrease.

At time t3, to which response delay until the detector 6 outputs a signal of a single shot after detection delay, and response delay of the control circuitry 5 has been added to time 2, the control circuitry 5 lowers the drive signal Vg1 to low (L) by the single shot, that is, for the prescribed period, and turns off the switching element 1 to make, the output from the gate drive circuitry 100 to the gate terminal of the main switching element 101, in the high-impedance state (step S3). As a result, injection of charges from the gate drive circuitry 100 into the gate terminal of the main switching element 101 or discharge from the gate terminal of the main switching element 101 to the gate drive circuitry 100 is temporarily stopped. Thus, the gate current Ig1 becomes zero as illustrated in FIG. 3. At this time, the conduction characteristics of the main switching element 101 temporarily stop changing. Thus, the drain-source voltage Vds1 of the main switching element 101 and the drain-source voltage Vds2 of the main switching element 102 also temporarily stop changing.

As described above, in the present embodiment: the detector 6 detects a timing as the timing serving as a trigger to start the prescribed period; the detected timing is a timing at which the drain current Id1 reaches a peak and starts to decrease so as to converge; the peak exceeding the drain current Id2, the drain current Id1 is a first current value of a current flowing through the main switching element 101; and the drain current Id2 is a second current value of a current flowing through the main switching element 102 when the main switching element 101 is in the state in which the main switching element 101 is kept turned off. The detector 6 outputs, to the control circuitry 5 of the controller 15, a signal indicating that the timing serving as a trigger to start the prescribed period has been detected. At this time, when detecting the timing serving as a trigger to start the prescribed period, the detector 6 outputs a pulse signal as the above-described signal to the control circuitry 5 of the controller 15 for a prescribed period, the pulse signal being in a state different from a state observed before detection of the timing. Note that the prescribed period for which the detector 6 outputs the pulse signal may be the same as or different from the prescribed period for which the gate drive circuitry 100 makes the output to the gate terminal of the main switching element 101 in the high-impedance state. The control circuitry 5 of the controller 15 makes the output to the gate terminal of the main switching element 101 in the high-impedance state for the prescribed period after a prescribed delay time elapses after acquisition of the signal from the detector 6.

Thereafter, when the control circuitry 5 returns the drive signal Vg1 to H at time t4, the gate drive circuitry 100 resumes driving, and injection of charges into the gate terminal of the main switching element 101 is also resumed. Thus, the switching of the main switching element 101 is resumed. That is, after the end of the prescribed period, the control circuitry 5 returns a state of the turn-on action of the main switching element 101 to a turn-on action state observed before the start of the prescribed period (step S4).

Thereafter, the drain-source voltage Vds1 of the main switching element 101 continues to decrease. Then, at time t5, the drain-source voltage Vds1 of the main switching element 101 completely decreases to 0 to several volts corresponding to the on-voltage of the main switching element 101, and the drain-source voltage Vds2 of the main switching element 102, which is paired with the main switching element 101, is maximized. At this time, a surge voltage, a ringing voltage, and the like of the drain-source voltage Vds2 of the main switching element 102 are low, and convergence of voltage oscillation is fast, unlike a general switching method.

Note that, in the present embodiment, since a switching action of the main switching element 101 is temporarily stopped partway through the switching action, an increase in the switching loss of the main switching element 101 is caused. However, a period from time t3 to time t4 is several tens of nanoseconds to several hundred nanoseconds or less. Thus, the influence on the loss is small.

In addition, since the gate drive circuitry 100 does not extract gate charges by outputting a negative voltage to be an off-pulse, the conduction characteristics of the main switching element 101 do not deteriorate, and an increase in loss is small.

Furthermore, it is possible to minimize deterioration of the switching loss of the main switching element 102 by setting a timing at which a step of the drain-source voltage Vds2 of the main switching element 102 occurs to a time point close to time t5, that is, close to a timing at which the drain-source voltage Vds1 of the main switching element 101 becomes 0 V.

In addition, since the speed of injection of charges into the gate terminal of the main switching element 101 in a period other than the period from time t3 to time t4 is the same as that in the normal switching action, the switching loss of the main switching element 101 does not deteriorate in the period other than the period from time t3 to time t4.

As described above, the gate drive circuitry 100 can suppress an increase in switching loss in the main switching element 101 and the main switching element 102 while suppressing occurrence of a ringing voltage in the main switching element 102, without requiring a switching circuitry that switches gate resistors.

Next, a hardware configuration of the gate drive circuitry 100 according to the first embodiment will be described. In the gate drive circuitry 100, the switching elements 1 and 2 are semiconductor elements such as MOSFETS as described above. The gate resistors 3 and 4 are resistors having desired resistance values. The direct-current power supplies 12 and 13 are power supply circuitries capable of outputting direct-current power. The detector 6 and the control circuitry 5 are implemented by processing circuitry. The processing circuitry may be a memory that stores programs, and a processor that executes the programs stored in the memory. Alternatively, the processing circuitry may be dedicated hardware.

FIG. 5 is a diagram showing an example of a configuration of processing circuitry 90 that implements the gate drive circuitry 100 according to the first embodiment in a case where the processing circuitry 90 includes a processor 91 and a memory 92. The processing circuitry 90 illustrated in FIG. 5 includes the processor 91 and the memory 92. In a case where the processing circuitry 90 includes the processor 91 and the memory 92, each function of the processing circuitry 90 is implemented by software, firmware, or a combination of software and firmware. The software or firmware is written as a program and stored in the memory 92. In the processing circuitry 90, the processor 91 reads out and executes the program stored in the memory 92 to implement each function. That is, the processing circuitry 90 includes the memory 92 for storing a program that, as a result, causes processing to be performed in the gate drive circuitry 100. It can also be said that this program is a program for causing the gate drive circuitry 100 to execute each function to be implemented by the processing circuitry 90. This program may be provided by means of a storage medium in which the program has been stored, or may be provided by other means such as a communication medium.

Here, the processor 91 is, for example, a central processing unit (CPU), a processing device, an arithmetic device, a microprocessor, a microcomputer, or a digital signal processor (DSP). Furthermore, examples of the memory 92 include nonvolatile or volatile semiconductor memories such as a random access memory (RAM), a read only memory (ROM), a flash memory, an erasable programmable ROM (EPROM), and an electrically EPROM (EEPROM (registered trademark)), a magnetic disk, a flexible disk, an optical disk, a compact disk, a mini disk, and a digital versatile disc (DVD).

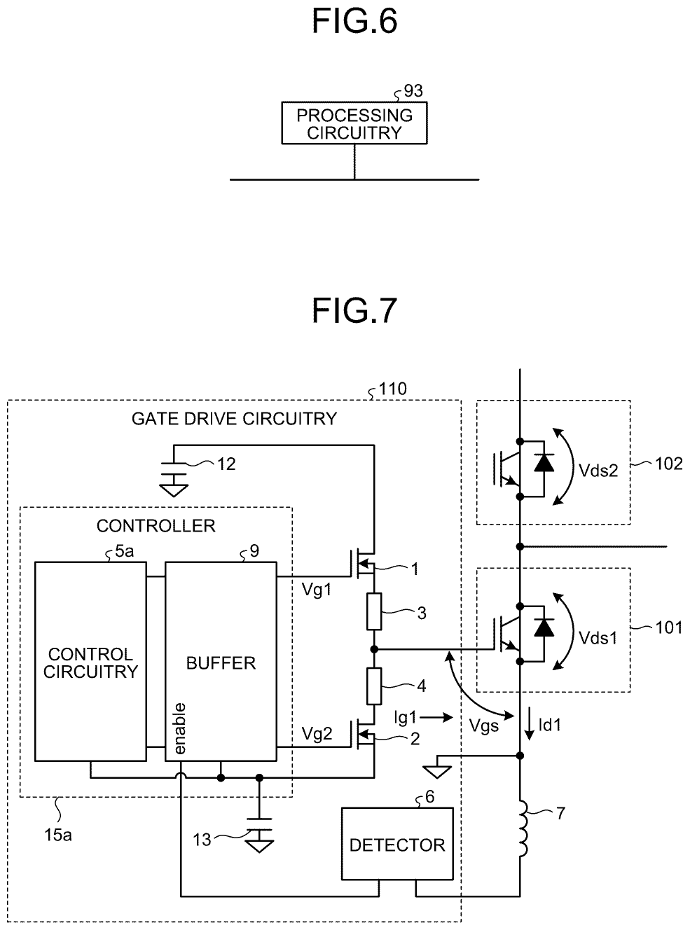

FIG. 6 is a diagram showing an example of a configuration of processing circuitry 93 that implements the gate drive circuitry 100 according to the first embodiment in a case where the processing circuitry 93 is implemented by dedicated hardware. The processing circuitry 93 illustrated in FIG. 6 corresponds to, for example, a single circuitry, a composite circuitry, a programmed processor, a parallel-programmed processor, an application specific integrated circuit (ASIC), a field-programmable gate array (FPGA), or a combination thereof. A part of the processing circuitry 93 may be implemented by dedicated hardware, and another part of the processing circuitry 93 may be implemented by software or firmware. Thus, the processing circuitry 93 can implement each of the above-described functions by means of dedicated hardware, software, firmware, or a combination thereof.

As described above, according to the present embodiment, the gate drive circuitry 100 makes output to the gate terminal of the main switching element 101 in a high-impedance state for a prescribed period when the drain-source voltage Vds1 of the main switching element 101 fluctuates during the turn-on action period. The turn-on action period is a period from a state change of the main switching element 101 to completion of the turning on of the main switching element 101. The state change is a change from a state in which the main switching element 101 is kept turned off to a state in which the main switching element 101 is in a turn-on state. The drain-source voltage Vds1 of the main switching element 101 is completely lowered when the turning on of the main switching element 101 is completed. After the end of the prescribed period, the gate drive circuitry 100 returns the output to the gate terminal of the main switching element 101 to a turn-on action state observed before the start of the prescribed period, and continues the turn-on action until the turning on of the main switching element 101 is completed. As a result, the gate drive circuitry 100 can suppress occurrence of a surge voltage of the main switching element 102 and suppress an increase in the switching loss of the main switching elements 101 and 102 while suppressing an increase in size in the system in which the main switching elements 101 and 102 are connected in series.

In the present embodiment, while attempting to achieve switching loss equivalent to that in the case of a general driving method by using the normal first voltage V1 first, the gate drive circuitry 100 brings the output to the gate terminal of the main switching element 101 into a high-impedance state during a change in the drain-source voltage Vds1 of the main switching element 101 after the gate voltage Vgs of the main switching element 101 reaches a mirror voltage. As a result, a change in the drain-source voltage Vds2 caused in the main switching element 102 paired with the main switching element 101 temporarily stops while the voltage is rising. Thereafter, the gate drive circuitry 100 returns the output to the gate terminal of the main switching element 101 to a driving state observed before the output to the gate terminal was brought into the high-impedance state. As a result, it is possible to suppress an increase in switching loss in the main switching elements 101 and 102 while suppressing occurrence of a ringing voltage in the main switching element 102, as compared with a general driving method.

### Second Embodiment

In a second embodiment, a description will be given of a case where a controller includes a buffer in a gate drive circuitry.

FIG. 7 is a diagram illustrating an exemplary configuration of a gate drive circuitry 110 according to the second embodiment. The gate drive circuitry 110 drives the main switching element 101 in a system in which the main switching elements 101 and 102 are connected in a totem-pole configuration, that is, connected in series, as illustrated in FIG. 7. Note that although not illustrated, the gate drive circuitry 110 can be applied to the power conversion system 200 as illustrated in FIG. 2, as with the gate drive circuitry 100 of the first embodiment.

The controller 15 in the gate drive circuitry 100 of the first embodiment has been replaced with a controller 15a to implement the gate drive circuitry 110 of the second embodiment. The controller 15a includes a control circuitry 5a and a buffer 9.

The control circuitry 5a outputs control signals for controlling the on/off of the switching elements 1 and 2. Unlike the control circuitry 5 of the first embodiment, the control circuitry 5a controls operation of the switching elements 1 and 2 via the buffer 9. In general, the control circuitry 5a often fails to output current and voltage necessary for the driving of the switching elements 1 and 2. Therefore, the controller 15a amplifies the control signals input from the control circuitry 5a by means of the buffer 9, and controls the operation of the switching elements 1 and 2.

The buffer 9 amplifies the control signals input from the control circuitry 5a to turn on and off the switching elements 1 and 2. The buffer 9 is, for example, a buffer circuitry including a half-bridge gate driver integrated circuit (IC) or the like. Furthermore, in the present embodiment, the buffer 9 includes a control terminal called an enable terminal or a reset terminal. The buffer 9 can lower both outputs from the buffer 9 to the switching elements 1 and 2 to L as a result of logical operation of the control terminal. Note that FIG. 7 shows an example in which the buffer 9 includes an enable terminal.

The detector 6 performs the same operation as in the first embodiment. Meanwhile, the detector 6 outputs a signal indicating that a timing serving as a trigger to start a prescribed period has been detected not to the control circuitry 5a but to the enable terminal of the buffer 9.

The buffer 9 has a function of controlling the operation of the switching elements 1 and 2 and bringing output to the gate terminal of the main switching element 101 into a high-impedance state, based on the signal acquired from the detector 6, the signal indicating that the timing serving as a trigger to start the prescribed period has been detected. The enable terminal included in the buffer 9 is originally a control terminal to be used when, for example, an anomaly occurs, or control power is lost. However, in the present embodiment, the signal output from the detector 6 is intentionally directed to the enable terminal of the buffer 9. As a result, the buffer 9 can fix both outputs on a high side and a low side, that is, both outputs to the switching elements 1 and 2 to L, and can bring the output from the gate drive circuitry 110 to the gate terminal of the main switching element 101 into the high-impedance state.

The other constituent elements operate in the same manner as in the first embodiment. Furthermore, the controller 15a of the second embodiment operates in the same manner as the controller 15 of the first embodiment. Therefore, description of specific operation of each constituent element will be omitted.

As described above, according to the present embodiment, the gate drive circuitry 110 is configured such that the controller 15a includes the control circuitry 5a and the buffer 9. Also in this case, the same effects as those of the gate drive circuitry 100 of the first embodiment can be obtained. Furthermore, the gate drive circuitry 110 is configured such that the buffer 9 acquires a signal from the detector 6. As a result, an existing control circuitry can be used as the control circuitry 5a. In addition, since there is no response delay, a high-speed response can be achieved. Thus, the switching of the high-impedance state can also be speeded up.

### Third Embodiment

In the first and second embodiments, the gate drive circuitries of a constant-voltage drive system have been described. In a third embodiment, a gate drive circuitry using a constant-current circuitry will be described.

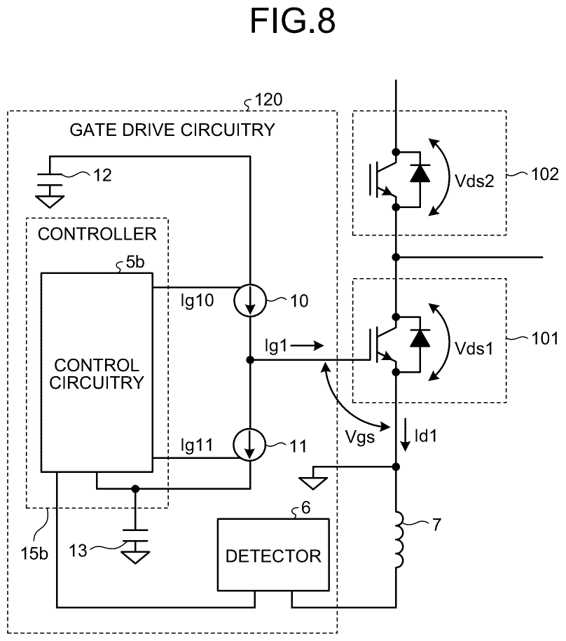

FIG. 8 is a diagram illustrating an exemplary configuration of a gate drive circuitry 120 according to the third embodiment. The gate drive circuitry 120 drives the main switching element 101 in a system in which the main switching elements 101 and 102 are connected in a totem-pole configuration, that is, connected in series, as illustrated in FIG. 8. Note that although not illustrated, the gate drive circuitry 120 can be applied to the power conversion system 200 as illustrated in FIG. 2, as with the gate drive circuitry 100 of the first embodiment.

The gate drive circuitry 120 of the third embodiment includes the detector 6, constant-current circuitries 10 and 11, the direct-current power supplies 12 and 13, and a controller 15b. The controller 15b includes a control circuitry 5b.

The constant-current circuitry 10 is a first constant-current circuitry having one end connected to the direct-current power supply 12 and capable of outputting a current from another end to the gate terminal of the main switching element 101.

The constant-current circuitry 11 is a second constant-current circuitry having one end connected to the direct-current power supply 13 and capable of outputting a current from another end to the gate terminal of the main switching element 101.

The control circuitry 5b of the controller 15b controls currents to be output to the gate terminal of the main switching element 101, or makes output to the gate terminal of the main switching element 101 in a high-impedance state, by individually controlling the constant-current circuitries 10 and 11. Specifically, the control circuitry 5b controls a current to be output from the constant-current circuitry 10 to the gate terminal of the main switching element 101, by means of a current command value Ig10 for the constant-current circuitry 10. In addition, the control circuitry 5b controls a current to be output from the constant-current circuitry 11 to the gate terminal of the main switching element 101, by means of a current command value Ig11 for the constant-current circuitry 11. At this time, the control circuitry 5b sets the current command value Ig10 for the constant-current circuitry 10 and the current command value Ig11 for the constant-current circuitry 11 such that both the current command value Ig10 and the current command value Ig11 are 0 A (zero ampere). As a result, injection of charges into or discharge from the gate terminal of the main switching element 101 is temporarily stopped to enable the output to the gate terminal of the main switching element 101 to be brought into the high-impedance state. As with the control circuitry 5 of the first embodiment, the control circuitry 5b brings the output to the gate terminal of the main switching element 101 into the high-impedance state based on a signal from the detector 6. Note that with regard to the current command value Ig10 for the constant-current circuitry 10 and the current command value Ig11 for the constant-current circuitry 11, the control circuitry 5b may output signals for instructing the constant-current circuitry 10 and the constant-current circuitry 11 to stop outputting currents, instead of instructing each of the constant-current circuitry 10 and the constant-current circuitry 11 to output a current of 0 A (zero ampere).

The gate drive circuitry 120 is different from the gate drive circuitry 100 of the first embodiment in that the gate drive circuitry 120 controls the output of currents to the gate terminal of the main switching element 101 while the gate drive circuitry 100 of the first embodiment controls the output of voltages to the gate terminal of the main switching element 101. Meanwhile, the gate drive circuitry 120 is similar in the flow of operation itself to the gate drive circuitry 100 of the first embodiment. Therefore, description of specific operation of each constituent element will be omitted.

As described above, in the present embodiment, the gate drive circuitry 120 brings the output to the gate terminal of the main switching element 101 into the high-impedance state by using the constant-current circuitries 10 and 11 to control the output of currents to the gate terminal of the main switching element 101. Also in this case, the gate drive circuitry 120 can obtain the same effects as those of the gate drive circuitry 100 of the first embodiment.

### Fourth Embodiment

In a fourth embodiment, a description will be given of another detection method in which the detector 6 detects a timing serving as a trigger to start a prescribed period based on the driving state of the main switching element 101. Here, the gate drive circuitry 100 of the first embodiment will be described as an example, but the present embodiment is also applicable to the gate drive circuitry 110 of the second embodiment and the gate drive circuitry 120 of the third embodiment.

For example, the detector 6 detects the timing of entering a mirror region based on a change in the gate voltage Vgs of the main switching element 101. In addition, the control circuitry 5 estimates a timing at which the drain-source voltage Vds1 of the main switching element 101 changes later than the detected timing, outputs a single-pulse signal, and brings the output to the gate terminal of the main switching element 101 into a high-impedance state. Thus, the same effects as in the first embodiment can be obtained.

That is, the detector 6 may detect a timing as the timing serving as a trigger to start the prescribed period, and may output, to the control circuitry 5 of the controller 15, a signal indicating that the timing serving as a trigger to start the prescribed period has been detected, the detected timing being a timing at which an amount of change in the gate voltage Vgs has decreased to enter the mirror region, the gate voltage Vgs being applied to the main switching element 101, the gate voltage Vgs being a mirror voltage in the mirror region. At this time, when detecting the timing serving as a trigger to start the prescribed period, the detector 6 outputs a pulse signal as the above-described signal to the control circuitry 5 of the controller 15 for a prescribed period, the pulse signal being in a state different from a state observed before detection of the timing. In this case, as a result of acquiring the signal from the detector 6, the control circuitry 5 of the controller 15 presumes that the drain-source voltage Vds1 of the main switching element 101 has started to decrease, and makes the output to the gate terminal of the main switching element 101 in the high-impedance state for the prescribed period after a prescribed delay time elapses after acquisition of the signal from the detector 6.

Note that operation of presuming that the drain-source voltage Vds1 of the main switching element 101 has started to decrease may be performed not by the control circuitry 5 of the controller 15 but by the detector 6.

In addition, the detector 6 observes the drain-source voltage Vds1 of the main switching element 101 to determine a timing at which the drain-source voltage Vds1 has changed, and causes the control circuitry 5 to output a single-pulse signal in accordance with the change to bring the output to the gate terminal of the main switching element 101 into a high-impedance state. Thus, the same effects as in the first embodiment can be obtained.

That is, the detector 6 may detect a timing at which the drain-source voltage Vds1 applied to the main switching element 101 has started to decrease as the timing serving as a trigger to start the prescribed period, and may output, to the control circuitry 5 of the controller 15, a signal indicating that the timing serving as a trigger to start the prescribed period has been detected. At this time, when detecting the timing serving as a trigger to start the prescribed period, the detector 6 outputs a pulse signal as the above-described signal to the control circuitry 5 of the controller 15 for a prescribed period, the pulse signal being in a state different from a state observed before detection of the timing. In this case, the control circuitry 5 of the controller 15 makes the output to the gate terminal of the main switching element 101 in the high-impedance state for the prescribed period after a prescribed delay time elapses after acquisition of the signal from the detector 6.

Note that the circuitry configurations of the gate drive circuitries described in the first to fourth embodiments are not limited to those described above. The gate drive circuitry may have any circuitry configuration as long as it is possible to bring a gate-source path of the main switching element 101, which is to be driven, in a high-impedance state just for a single-shot time.

The configurations set forth in the above embodiments show examples, and it is possible to combine the configurations with another known technique or combine the embodiments with each other, and is also possible to partially omit or change the configurations without departing from the scope of the present disclosure.

### REFERENCE SIGNS LIST

1, 2 switching element; 3, 4 gate resistor; 5, 5a, 5b control circuitry; 6 detector; 7 reactor; 9 buffer; 10, 11 constant-current circuitry; 12, 13, 150 direct-current power supply; 15, 15a, 15b controller; 90, 93 processing circuitry; 91 processor; 92 memory; 100, 100a to 100f, 110, 120 gate drive circuitry; 101, 101a to 101c, 102, 102a to 102c main switching element; 160 motor; 200 power conversion system.

1.-8. (canceled)

9. A gate drive circuitry configured to make a first main switching element a target to be driven, wherein the first main switching element and a second main switching element are connected in series, the gate drive circuitry comprising:
a controller configured to:
make output to a gate terminal of the first main switching element in a high-impedance state for a prescribed period when a drain-source voltage of the first main switching element fluctuates during a turn-on action period that is a period from a state change of the first main switching element to completion of turning on of the first main switching element, wherein
the state change is a change from a state in which the first main switching element is kept turned off to a state in which the first main switching element is in a turn-on state,
the drain-source voltage of the first main switching element being completely lowered when the turning on of the first main switching element is completed: and
return the output to the gate terminal of the first main switching element to a turn-on action state after the prescribed period ends, the turn-on action state being a state observed before a start of the prescribed period, and continuing a turn-on action until the turning on of the first main switching element is completed, wherein
the prescribed period continues until a gate current of the first main switching element temporarily becomes zero, or until the drain-source voltage of the first main switching element and a drain-source voltage of the second main switching element temporarily stop changing.

10. The gate drive circuitry according to claim 9, further comprising a detector configured to detect a timing serving as a trigger to start the prescribed period, wherein
the detector is configured to:
detect a timing as the timing serving as the trigger to start the prescribed period; and
output, to the controller, a signal indicating that the timing serving as the trigger to start the prescribed period has been detected, the detected timing being a timing at which a first current value reaches a peak and starts to decrease so as to converge, the peak exceeding a second current value, the first current value being a current value of a current flowing through the first main switching element, the second current value being a current value of a current flowing through the second main switching element when the first main switching element is in the state in which the first main switching element is kept turned off, and
the controller is configured to make the output to the gate terminal of the first main switching element in the high-impedance state for the prescribed period after a prescribed delay time elapses after acquisition of the signal.

11. The gate drive circuitry according to claim 9, further comprising a detector configured to detect a timing serving as a trigger to start the prescribed period, wherein
the detector is configured to:
detect a timing as the timing serving as the trigger to start the prescribed period; and
output, to the controller, a signal indicating that the timing serving as the trigger to start the prescribed period has been detected, the detected timing being a timing at which the drain-source voltage starts to decrease, the drain-source voltage being applied to the first main switching element, and
the controller is configured to make the output to the gate terminal of the first main switching element in the high-impedance state for the prescribed period after a prescribed delay time elapses after acquisition of the signal.

12. The gate drive circuitry according to claim 9, further comprising a detector configured to detect a timing serving as a trigger to start the prescribed period, wherein
the detector is configured to:
detect a timing as the timing serving as the trigger to start the prescribed period; and
output, to the controller, a signal indicating that the timing serving as the trigger to start the prescribed period has been detected, the detected timing being a timing at which an amount of change in gate voltage has decreased to enter a mirror region, the gate voltage being applied to the first main switching element, the gate voltage being a mirror voltage in the mirror region, and
as a result of acquiring the signal, the controller is configured to:
presume that the drain-source voltage of the first main switching element has started to decrease; and
make the output to the gate terminal of the first main switching element in the high-impedance state for the prescribed period after a prescribed delay time elapses after acquisition of the signal.

13. The gate drive circuitry according to claim 10, wherein
when detecting the timing serving as the trigger to start the prescribed period, the detector is configured to output a pulse signal as the signal to the controller for a prescribed period, the pulse signal being in a state different from a state observed before detection of the timing.

14. The gate drive circuitry according to claim 11, wherein
when detecting the timing serving as the trigger to start the prescribed period, the detector is configured to output a pulse signal as the signal to the controller for a prescribed period, the pulse signal being in a state different from a state observed before detection of the timing.

15. The gate drive circuitry according to claim 12, wherein
when detecting the timing serving as the trigger to start the prescribed period, the detector is configured to output a pulse signal as the signal to the controller for a prescribed period, the pulse signal being in a state different from a state observed before detection of the timing.

16. The gate drive circuitry according to claim 9, further comprising:
a first switching element with one end connected to a first direct-current power supply, the first switching element being capable of outputting a voltage from another end to the gate terminal of the first main switching element; and
a second switching element with one end connected to a second direct-current power supply, the second switching element being capable of outputting a voltage from another end to the gate terminal of the first main switching element, wherein
by individually controlling on/off of the first switching element and the second switching element, the controller is configured to:
control the voltages to be output to the gate terminal of the first main switching element; or
make the output to the gate terminal of the first main switching element in the high-impedance state.

17. The gate drive circuitry according to claim 16, wherein
the controller includes:
a control circuitry configured to output control signals for controlling the on/off of the first switching element and the second switching element; and
a buffer configured to turn on and off the first switching element and the second switching element by amplifying the control signals, and
the buffer has a function of controlling operation of the first switching element and the second switching element and making the output to the gate terminal of the first main switching element in the high-impedance state, based on a signal acquired from the detector configured to detect a timing serving as a trigger to start the prescribed period, the signal indicating that the timing serving as the trigger to start the prescribed period has been detected.

18. The gate drive circuitry according to claim 9, further comprising:
a first constant-current circuitry with one end connected to a first direct-current power supply, the first constant-current circuitry being capable of outputting a current from another end to the gate terminal of the first main switching element; and
a second constant-current circuitry with one end connected to a second direct-current power supply, the second constant-current circuitry being capable of outputting a current from another end to the gate terminal of the first main switching element, wherein
by individually controlling the first constant-current circuitry and the second constant-current circuitry, the controller is configured to:
control the currents to be output to the gate terminal of the first main switching element; or
make the output to the gate terminal of the first main switching element in the high-impedance state.
